(19) United States
(12) Patent Application Publication
(10) Pub. No.: US 2018/0182652 A1
(43) Pub. Date: Jun. 28, 2018

(54) SUBSTRATE PROCESSING APPARATUS, SUBSTRATE PROCESSING METHOD, AND SUBSTRATE PROCESSING SYSTEM

(71) Applicant: TOKYO ELECTRON LIMITED, Tokyo (JP)

(72) Inventors: Yuji SESHIMO, Nirasaki City (JP); Yoshihiro TAKEZAWA, Nirasaki City (JP); Shigeru NAKAJIMA, Nirasaki City (JP)

(21) Appl. No.: 15/844,707

(22) Filed: Dec. 18, 2017

(30) Foreign Application Priority Data
Dec. 22, 2016 (JP) 2016-249298

(51) Int. Cl. H01L 21/67; H01J 37/32; H01J 11/34

(52) U.S. Cl. CPC H01L 21/67167; G05B 2219/45031; H01J 11/34; H01J 37/32798

(57) ABSTRACT

A substrate processing apparatus includes a base member having an opening, a substrate holding member fixedly provided on the base member and configured to hold a plurality of substrates in multiple stages in a vertical direction, a plurality of shower plates provided to respectively face the substrates held by the substrate holding member and configured to supply a processing gas to the substrates existing thereunder in a shower shape, at least one gas introduction member configured to introduce the processing gas into the shower plates, a processing container provided to be able to make close contact with the base member and brought into close contact with the base member to define an arrangement space of the substrate holding member as a processing chamber, a heating device configured to heat the substrates in the processing chamber, and an exhaust mechanism configured to evacuate the processing chamber through the opening.

### CROSS-REFERENCE TO RELATED APPLICATION

This application is based upon and claims the benefit of priority from Japanese Patent Application No. 2016-249298, filed on Dec. 22, 2016, the entire contents of which are incorporated herein by reference.

### TECHNICAL FIELD

The present disclosure relates to a substrate processing apparatus, a substrate processing method, and a substrate processing system, which perform processing on a plurality of substrates arranged in multiple stages in a vertical direction.

### BACKGROUND

For example, in the manufacture of a semiconductor device, when a process such as a diffusion process, an annealing process, a film forming process, an oxidation process or the like is performed on a semiconductor wafer (wafer) as a substrate to be processed, there is widely used a batch type vertical heat treatment apparatus in which a quartz-made boat holding a plurality of wafers vertically arranged in multiple stages is loaded into a vertical quartz-made processing container from below, a processing gas is introduced into the processing container by a gas injector inserted into the processing container, and the wafers are heated and processed by a heater provided around the processing container.

In such a batch type vertical heat treatment apparatus, from the viewpoint of uniformly supplying the processing gas to a plurality of wafers in the processing container, there is also used a technique that makes use of a gas injector extending in an arrangement direction of substrates and having a plurality of gas discharge holes at the positions corresponding to the respective wafers.

However, in recent years, the miniaturization of a semiconductor device and the complication of a structure thereof have been progressing rapidly. Thus, sufficient uniformity cannot be obtained even if the gas injector mentioned above is used.

In particular, when a predetermined film is formed on a wafer having a high-aspect-ratio trench formed on its surface, high film thickness uniformity and high coverage are required. However, it is difficult for the aforementioned technique to meet such requirements.

### SUMMARY

Some embodiments of the present disclosure provide a substrate processing apparatus, a substrate processing method, and a substrate processing system, which are capable of performing processing with high uniformity on a plurality of substrates arranged in multiple stages in a vertical direction.

According to one embodiment of the present disclosure, there is provided a substrate processing apparatus for performing a predetermined process on a substrate to be processed, including: a base member having an opening portion; a substrate holding member fixedly provided on the base member and configured to hold a plurality of substrates in multiple stages in a vertical direction at predetermined intervals; a plurality of shower plates provided so as to respectively face the substrates held by the substrate holding member and configured to supply a processing gas to the substrates existing thereunder in a shower shape; at least one gas introduction member provided integrally with the substrate holding member and configured to introduce the processing gas into the shower plates; a processing container provided so as to be able to make close contact with the base member and brought into close contact with the base member to define an arrangement space of the substrate holding member as a processing chamber; a heating device configured to heat the substrates in the processing chamber; and an exhaust mechanism configured to evacuate the processing chamber through the opening portion of the base member.

According to another embodiment of the present disclosure, there is provided a substrate processing method using a substrate processing apparatus which includes: a base member having an opening portion; a substrate holding member fixedly provided on the base member and configured to hold a plurality of substrates in multiple stages in a vertical direction at predetermined intervals; a plurality of shower plates provided so as to respectively face the substrates held by the substrate holding member and configured to supply a processing gas to the substrates existing thereunder in a shower shape; at least one gas introduction member provided integrally with the substrate holding member and configured to introduce the processing gas into the shower plates; a processing container provided so as to be able to make close contact with the base member and brought into close contact with the base member to define an arrangement space of the substrate holding member as a processing chamber; a heating device configured to heat the substrates in the processing chamber; and an exhaust mechanism configured to evacuate the processing chamber through the opening portion of the base member, the method including: retracting the processing container and the heating device to a retracted position above the substrate holding member and transferring the substrates to the substrate holding member; moving the processing container and the heating device downward and bringing the processing container into close contact with the base member to define the processing chamber; evacuating the processing chamber; supplying the processing gas introduced from the gas introducing member into the shower plates to the substrates respectively provided under the shower plates in a shower shape to perform predetermined processing; returning the interior of the processing chamber to an atmospheric pressure after processing; and retracting the processing container and the heating device to the retracted position above the substrate holding member and unloading the processed substrates from the substrate holding member.

According to another embodiment of the present disclosure, there is provided a substrate processing system, including: a plurality of substrate processing parts each including a base member having an opening portion, a substrate holding member fixedly provided on the base member and configured to hold a plurality of substrates in multiple stages in a vertical direction at predetermined intervals, a plurality of shower plates provided so as to respectively face the substrates held by the substrate holding member and configured to supply a processing gas to the substrates existing thereunder in a shower shape, at least one gas introduction member provided integrally with the substrate holding member and configured to introduce the processing gas into the shower plates, a processing container provided so as to be able to make close contact with the base member and brought into close contact with the base member to define an arrangement space of the substrate holding member as a processing chamber, a heating device configured to heat the substrates in the processing chamber, an exhaust mechanism configured to evacuate the processing chamber through the opening portion of the base member, and an elevating mechanism configured to integrally move the processing container and the heating device up and down between a processing position where the processing container and the base member are brought into close contact with each other to define the processing chamber and a retracted position above the substrate holding member, and a common transfer device configured to transfer the substrates to and from the substrate holding members of the substrate processing parts.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view showing a schematic configuration of a substrate processing apparatus according to an embodiment of the present disclosure.

FIG. 2 is a view showing a state in which a container unit is moved upward in the substrate processing apparatus shown in FIG. 1.

FIG. 3 is a vertical sectional view showing a detailed structure of a wafer boat used in the substrate processing apparatus shown in FIG. 1.

FIG. 4 is a horizontal sectional view showing the detailed structure of the wafer boat used in the substrate processing apparatus shown in FIG. 1.

FIG. 5 is a horizontal sectional view showing an example in which a part of a gas supplied to a gas introduction part of the wafer boat is converted into plasma by a remote plasma source.

FIG. 6 is a sectional view showing an example in which a plasma generating mechanism is provided in the substrate processing apparatus shown in FIG. 1.

FIG. 7 is a plan view showing a substrate processing system to which the substrate processing apparatus shown in FIG. 1 is applied.

FIG. 8 is a sectional view showing another example of a shower plate.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Configuration of Substrate Processing Apparatus>

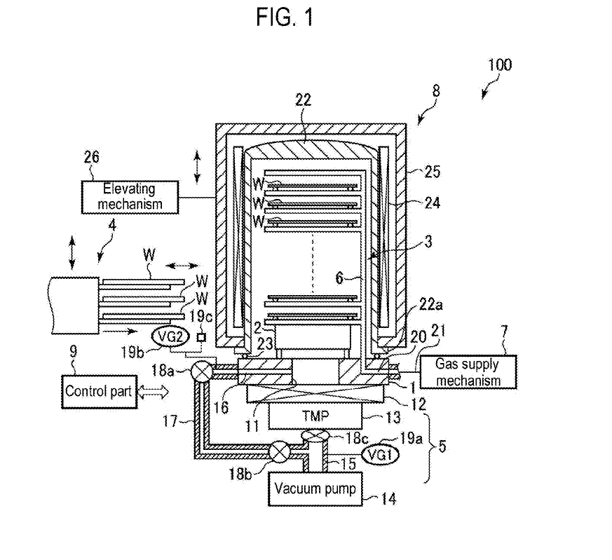

First, the configuration of a substrate processing apparatus according to an embodiment of the present disclosure will be described. FIG. 1 is a sectional view showing a schematic configuration of a substrate processing apparatus according to an embodiment of the present disclosure.

The substrate processing apparatus of the present embodiment is configured as a vertical heat treatment apparatus and is applicable to substrate processing, for example, an annealing process, an oxidation process, a film forming process using a chemical vapor deposition method (CVD method), an atomic layer deposition method (ALD method) or the like, a thermal etching process (deposition-etching-deposition process), a chemical oxide removal (COR) process, and the like.

The substrate processing apparatus 100 of the present embodiment includes a manifold 1 as a fixed base member. A wafer boat 3 as a wafer holding member capable of holding a plurality of, for example, 5 to 50 semiconductor wafers (hereinafter simply referred to as wafers) W in multiple stages in a vertical direction is fixedly disposed on the manifold 1 via a heat insulating cylinder 2. On the lateral side of the wafer boat 3, a transfer device 4 for transferring the wafers W to and from the wafer boat 3 is provided so as to be able to move up and down and move toward and away from the wafer boat 3.

An opening portion 11 used for exhausting is formed at the center of the manifold 1. A turbo molecular pump (TMP) 13 is connected to the lower side of the manifold 1 via a gate valve 12. A vacuum pump 14 such as a rotary pump or the like as a rough-drawing auxiliary pump is connected to the lower side of the turbo molecular pump 13 via a pipe 15. The turbo molecular pump 13 and the vacuum pump 14 constitute an exhaust mechanism 5. The diameter of the opening portion 11 is set to a diameter suitable for the turbo molecular pump 13.

The manifold 1 has an exhaust passage 16 provided horizontally so as to be connected to the opening portion 11. One end of a bypass pipe 17 is connected to the exhaust passage 16. The other end of the bypass pipe 17 is connected to the pipe 15. In the bypass pipe 17, there are provided a first valve 18a on the manifold side and a second valve 18b on the side of the pipe 15. A third valve 18c is provided in the pipe 15 just below the turbo molecular pump 13. A first vacuum gauge (VG1) 19a that can measure a pressure from 0 Torr to an atmospheric pressure is provided in the pipe 15. A second vacuum gauge (VG2) 19b for high vacuum and a sampling port 19c for analyzing a gas existing in a reaction chamber are provided on the upstream side of the first valve 18a in the bypass pipe 17.

The turbo molecular pump 13 is a molecular pump which includes a rotor (movable blade) having turbine type blades and a stator (fixed blade). The turbo molecular pump 13 maintains a constant exhaust velocity in a molecular flow region and can continuously exhaust gas. The turbo molecular pump 13 enables a pressure to reach a high vacuum region of 10⁻⁵ to 10⁻⁶ Torr, which is higher than a vacuum region of an ordinary vacuum pump. However, the turbo molecular pump 13 cannot perform vacuum drawing directly from the atmosphere. Therefore, the gate valve 12 and the third valve 18c are first closed. The first valve 18a and the second valve 18b are opened. Vacuum drawing is performed to a predetermined degree of vacuum via the bypass pipe 17 by the vacuum pump 14 as an auxiliary pump. After reaching the predetermined degree of vacuum, the gate valve 12 and the third valve 18c are opened. The first valve 18a and the second valve 18b are closed. Vacuum drawing is performed to high vacuum by the turbo molecular pump 13. The degree of vacuum during rough drawing can be monitored by the first vacuum gauge 19a. The degree of vacuum in the high vacuum state available when operating the turbo molecular pump 13 can be monitored by the second vacuum gauge 19b. The degree of vacuum available when operating the turbo molecular pump 13 can be controlled by the rotational speed of the rotor.

The wafer boat 3 is integrated with a gas introduction member (gas injector). Specifically, the wafer boat 3 includes a plurality of support pillars extending in the vertical direction. At least one of the support pillars constitutes a gas introduction member 6 for introducing a gas such as a processing gas or the like to the arrangement positions of the wafers W. The gas introduction member 6 is connected to a gas supply mechanism 7 via a gas flow path 20 provided in the manifold 1 and a pipe 21. In the case of supplying a plurality of gases, the gas supply mechanism 7 includes a plurality of gas supply sources and includes pipes 21 and gas flow paths 20 corresponding in number to the gas supply sources. A plurality of gas introduction members 6 is respectively connected to the plurality of gas flow paths 20. A flow rate controller (not shown) such as a mass flow controller or the like and a valve (not shown) are provided in the pipe 21. At least one of the supplied gases may be converted into plasma so that plasma processing can be performed.

Since the wafer boat 3 is provided integrally with the gas introduction member 6, the wafer boat 3 does not rotate.

Around the wafer boat 3, a cylindrical processing container 22 having a ceiling is disposed so as to define a processing chamber as a closed space therein. A flange 22a is formed at the lower end of the processing container 22. A gap between the flange 22a and the manifold 1 can be hermetically sealed via a seal ring 23. A heater 24 for heating the wafers W is provided on the outer periphery of the processing container 22. On the outer side of the heater 24, there is provided a housing 25 which supports the processing container 22 and the heater 24 and includes a water-cooling jacket (not shown) and a heat insulating material (not shown). The processing container 22, the heater 24 and the housing 25 are integrated to constitute a container unit 8.

Quartz or SiC may be suitably used as the material of the processing container 22. Depending on the heating temperature and the arrangement of the heater 24, the processing container 22 may also be made of metal (aluminum or the like). The thickness of the processing container 22 may be appropriately changed according to the degree of vacuum required. When a higher degree of vacuum is required, it is possible to double the seal ring 23 or to use a gasket instead of the seal ring.

A resistor-heating-type heater may be used as the heater 24. Carbon, ceramic or metal (tungsten) may be used as the material of the heater 24. Alternatively, lamp heating may be used. In this example, the heater 24 is provided circumferentially around the cylindrical processing container. However, the processing container 22 may have a rectangular tube shape and the heater 24 may be disposed on the four sides thereof. In addition, the arrangement position of the heater 24 is not limited to the surroundings of the processing container 22. A bottom heater or the like may be used.

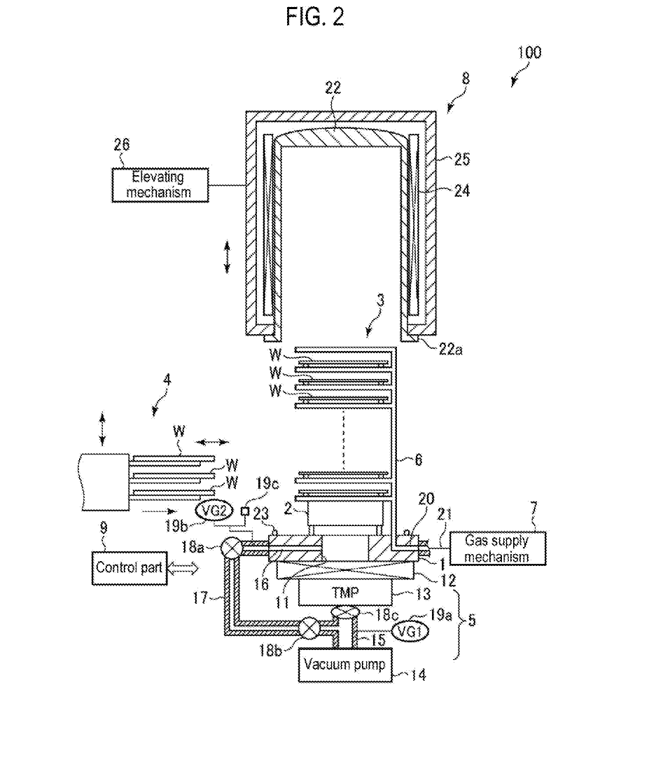

The container unit 8 can be moved up and down by an elevating mechanism 26 between a processing position where the container unit 8 is moved down as shown in FIG. 1 so that the processing container 22 and the manifold 1 can form a processing chamber as a closed space and a retracted position where the container unit 8 is moved up away from the wafer boat 3 as shown in FIG. 2 so that the transfer device 4 can transfer the wafers to and from the wafer boat 3.

The substrate processing apparatus 100 includes a control part 9. The control part 9 controls the respective components of the substrate processing apparatus 100, for example, the transfer device 4, the valves, the mass flow controller as a flow rate controller, the elevating mechanism 26, the heater power supply, the drive mechanisms for the pumps 13 and 14. The control part 9 includes a CPU (computer) and further includes a main control unit for performing the above control, an input device, an output device, a display device, and a storage device. A storage medium storing a program, i.e., a process recipe, for controlling a process executed by the substrate processing apparatus 100 is set in the storage device. The main control unit reads out a predetermined process recipe stored in the storage medium and controls the substrate processing apparatus 100 to perform a predetermined process based on the process recipe.

### <Details of Wafer Boat>

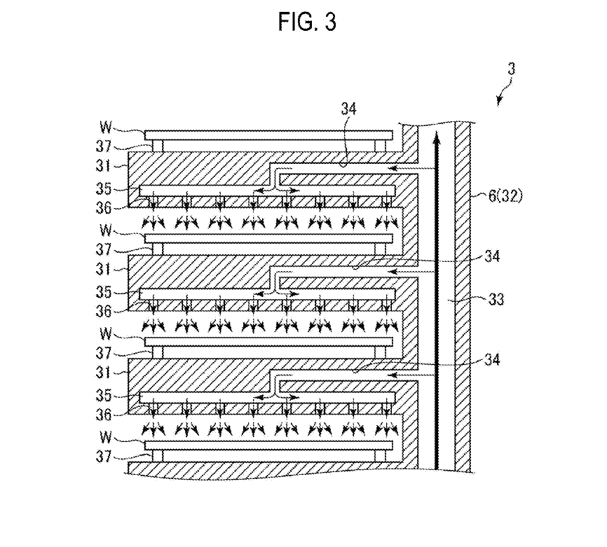

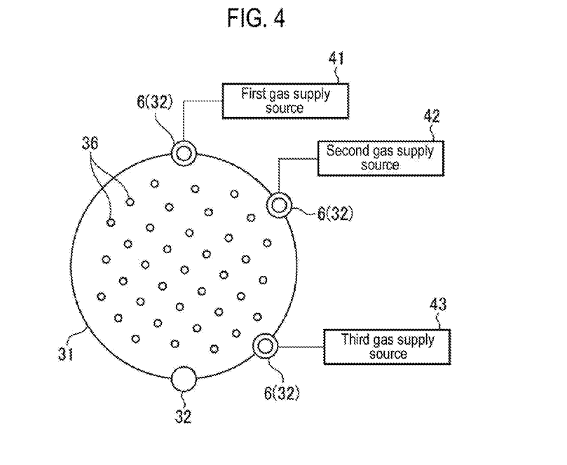

Next, the wafer boat 3 will be described in detail. FIG. 3 is a vertical sectional view showing the detailed structure of the wafer boat. FIG. 4 is a horizontal sectional view thereof.

The wafer boat 3 includes a plurality of shower plates 31 that supports a plurality of wafers W in multiple stages in the vertical direction and faces the plurality of wafers W, respectively. The wafer boat 3 includes a plurality of support pillars 32 for supporting the shower plates 31. At least one of the support pillars 32 serves as a gas introduction member 6. A main gas flow path 33 extending in the vertical direction is formed in the gas introduction member 6. The main gas flow path 33 is connected to branch flow paths (processing gas introduction paths) 34 for supplying a gas to the respective shower plates 31. The branch flow path 34 extends to the center of the shower plate 31 corresponding to the central portion of the wafer W. The branch flow path 34 is connected to a circular gas diffusion space 35 formed below the branch flow path 34 and having a diameter substantially corresponding to the diameter of the wafer W. On the bottom surface of the shower plate 31, there is formed a plurality of gas discharge holes 36 for discharging the processing gas diffused in the gas diffusion space 35.

The wafer W is supported on the upper surface of the shower plate 31 by support members 37. The processing gas discharged from the gas discharge holes 36 of the opposing shower plate 31 disposed above the wafer W is supplied to the wafer W.

In this manner, the processing gas supplied from the gas supply mechanism 7 flows through the main gas flow path 33 in the gas introduction member 6 utilizing the support pillars 32, which are the components of the wafer boat 3. The processing gas is directly supplied to the wafer W in a shower shape via the main gas flow path 33, the branch flow path 34, the gas diffusion space 35 and the gas discharge holes 36. This makes it possible to more uniformly supply the processing gas to the wafer W.

FIG. 4 shows a case in which four support pillars 32 are provided in the wafer boat 3 and three of the support pillars 32 function as gas introduction members 6. A first gas supply source 41, a second gas supply source 42 and a third gas supply source 43 are respectively connected to the three gas introduction members 6. Three processing gases are supplied. Of course, the number of the gas supply sources and the number of the gas introduction members 6 are not limited and may be the same as the number of the processing gases required for processing. In addition, the number of the support pillars 32 is not limited to four. When the number of required processing gases is large, the number of the support pillars 32 used as the gas introduction members 6 may be increased accordingly. In general, a purge gas is supplied as one of the processing gases. The purge gas may be directly introduced into the processing chamber without passing through the shower plate 31.

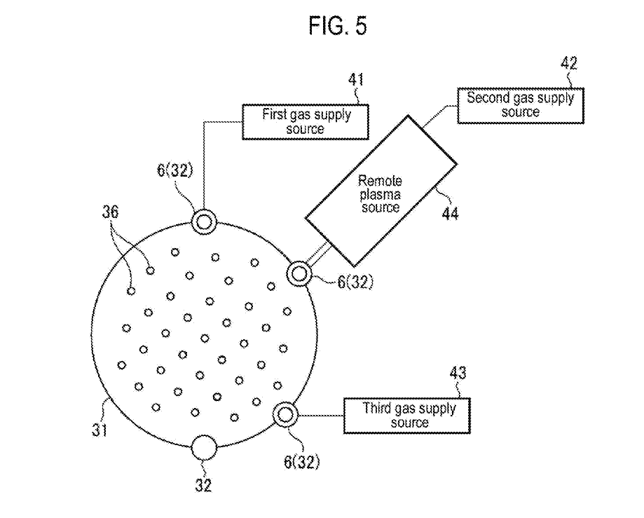

The substrate processing apparatus 100 of the present embodiment may also be applied to a case which includes processing by active species. In the example of FIG. 5, a first gas supply source 41, a second gas supply source 42 and a third gas supply source 43 are respectively connected to the three gas introduction members 6. The second gas supply source 42 is connected to a remote plasma source 44. The remote plasma source 44 converts the processing gas supplied from the second gas supply source 42 into plasma and supplies plasma (radicals) to the wafer W via the gas introduction member 6. The plasma generation method of the remote plasma source 44 is not particularly limited. Various methods such as a capacitively coupled plasma generation method, an inductively coupled plasma generation method, a microwave plasma generation method and the like may be used.

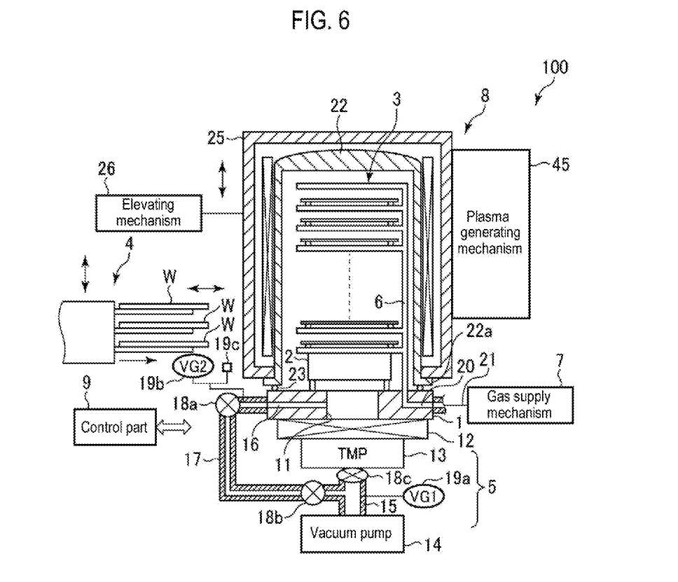

As shown in FIG. 6, a plasma generating mechanism 45 may be provided adjacent to the processing container 22 so that plasma can be generated in the processing container 22 to perform plasma processing. The plasma generating mechanism 45 is moved up and down together with the container unit 8. As for the plasma generating mechanism 45, the plasma generation method is not particularly limited. Various methods such as a capacitively coupled plasma generation method, an inductively coupled plasma generation method, a microwave plasma generation method and the like may be used.

### <Operation of Substrate Processing Apparatus>

Next, the operation of the substrate processing apparatus configured as above will be described. First, in the state of FIG. 2 in which the container unit 8 is moved up, the wafers W are transferred to the wafer boat 3 by the transfer device 4.

When the transfer of the wafers W to the wafer boat 3 is completed, the container unit 8 is moved down so that as shown in FIG. 1, the flange 22a of the processing container 22 and the manifold 1 are brought into close contact with each other through the seal ring 23 to form a processing chamber.

Subsequently, the gate valve 12 and the third valve 18c are closed, and the first valve 18a and the second valve 18b are opened. In this state, vacuum drawing is performed to a predetermined degree of vacuum via the bypass pipe 17 by the vacuum pump 14 serving as an auxiliary pump. Thereafter, the first valve 18a and the second valve 18b are closed. The gate valve 12 and the third valve 18c are opened. A high vacuum state of about 10⁻⁵ to 10⁻⁶ Torr is established by the turbo molecular pump 13. At this time, the degree of vacuum is adjusted by the rotational speed of the rotor of the turbo molecular pump 13.

Thereafter, the interior of the processing chamber is purged by a purge gas. Subsequently, a predetermined processing gas is supplied from the gas supply mechanism 7 via the pipe 21 and the gas flow path 20 in the manifold 1 to the gas introduction member 6 formed in the support pillar 32 of the wafer boat 3. The supplied processing gas passes through the main gas flow path 33 inside the gas introduction member 6 and is introduced into the branch flow path 34 of the shower plate 31 provided to face each of the wafers W. The processing gas is discharged toward the wafer W via the gas diffusion space 35 and the gas discharge holes 36, whereby a predetermined process is performed on the wafer W.

The processing temperature at this time is appropriately set, for example, between 200 degrees C. and 1000 degrees C. depending on the substrate processing.

In the substrate processing apparatus of the present embodiment, an appropriate processing gas may be used depending on the processing to be applied. For example, when an annealing process is performed, Ar, NH₃, H₂ or N₂ may be used. In the case of performing an oxidation process, O₂, O₃, H₂O may be used. In the case of forming, for example, a SiN film or an SiO₂ film by thermal CVD or plasma CVD, an inorganic silicon compound such as dichlorosilane (SiH₂Cl₂), tetrachlorosilane (SiCl₄), disilicon hexachloride (Si₂Cl₆) or the like, or an organic silicon compound such as tetraethoxysilane (TEOS), bis (tertiary) butyl aminosilane (BTBAS) or the like may be used. In the case of forming an epitaxial film such as Si or GaN by thermal CVD or plasma CVD, trimethyl gallium (Ga(CH₃)₃), gallium trichloride (GaCl₃), a silane-based compound or like may be used. In addition, an oxide film such as ZrO₂, HfO₂, TiO₂, Al₂O₃, SiO₂ or the like, a nitride film such as HfN, TiN, AlN, SiN or the like, or a composite film obtained by combining the above compounds, such as ZrAlO, HfAlO, HfSiON or the like, may be formed by CVD or ALD. In this case, a raw material gas (precursor) and a reaction gas (oxidizing gas or nitriding gas) corresponding to these films may be used. In the case of CVD, the raw material gas and the reaction gas are supplied at the same time. In the case of ALD, the raw material gas and the reaction gas are sequentially supplied. After supplying the raw material gas and the reaction gas, the inside of the processing chamber is purged.

For example, in the case of forming a HfO₂ film which is a high-k film, an organic hafnium compound such as tetrakis(dimethylamino)hafnium (Hf(NCH₃)₂)₄: TDMAH) or the like, hafnium chloride (HfCl₄), or the like may be used as the raw material gas. An oxidizing agent such as an O₃ gas, a H₂O gas, an O₂ gas, an NO₂ gas, an NO gas, an N₂O gas, plasma of an O₂ gas or the like may be used as the reaction gas.

As described above, the processing gas supplied from the gas supply mechanism 7 is introduced into the shower plate 31 through the gas introduction member 6 integrated with the wafer boat 3, specifically, the gas introduction member 6 configured by the support pillar 32 which is a component of the wafer boat 3, and is uniformly discharged from the gas discharge holes 36 of the shower plate 31 directly to the wafer arrangement region. Therefore, the processing gas is uniformly supplied to the wafer W from above and the wafer boat 3. Even though the wafer boat 3 does not rotate, it is possible to carry out the processing with higher uniformity than conventionally with respect to the wafer W.

In particular, the shower plate 31 provided in the wafer boat 3 guides the processing gas introduced from the gas introduction member 6 to the center of the shower plate 31 using the branch flow path 34. The processing gas supplied from the center of the shower plate 31 passes through the gas diffusion space 35 and is discharged from the gas discharge holes 36 to the wafer W. Therefore, the amount and pressure of the processing gas discharged from the gas discharge holes 36 is more uniform, and the uniformity of processing is higher.

In a conventional vertical heat treatment apparatus, a wafer boat on which wafers W are mounted in multiple stages is inserted into a processing container. While rotating the wafer boat, a processing gas is introduced through gas discharge holes of a gas injector provided separately from the wafer boat. The processing gas forms a gas flow (cross flow) parallel to the surface of the wafer W. Therefore, even when the wafer boat is rotated, it is difficult for the processing gas to reach the central portion of the wafer W. Since the shape of a device formed on the wafer W is becoming more intricate and the structure thereof is growing more complicated, it is becoming difficult to uniformly supply a gas to the wafer W.

On the other hand, in the present embodiment, the processing gas is supplied to the wafer W in a shower shape from the gas introduction member 6 integrated with the wafer boat 3 through the gas discharge holes 36 of the shower plate 31. It is therefore possible to more uniformly supply the processing gas to the wafer W.

In particular, when a predetermined film is formed by CVD or ALD on the wafer W on which a trench with a high aspect ratio is formed, in addition to the uniformity of the film thickness due to the uniform supply of the processing gas, there is also provided an effect that, since a gas flow is supplied from the shower plate 31 existing above the wafer W to the surface of the wafer W, the processing gas is sufficiently supplied even to a recess such as a trench or the like, which makes it possible to enhance the coverage performance Above all, in the case of ALD which essentially shows high uniformity and high coverage performance, it is possible to obtain higher effects.

Furthermore, in the substrate processing apparatus 100 of the present embodiment, the gas introduction member 6 is integrally provided with the wafer boat 3. Therefore, the wafer boat 3 is fixedly provided together with the manifold 1. Thus, the container unit 8 including the processing container 22 and the heater 24 is move up and down while transferring the wafer W.

In the case of such a structure, unlike the conventional case, it is unnecessary to load and unload the wafer boat from the lower side of the processing container. This makes it possible to exhaust the processing container 22 through the opening portion 11 of the manifold 1 that closes the bottom of the processing container 22. Therefore, in the present embodiment, the opening portion 11 of the manifold 1 has a diameter suitable for the turbo molecular pump 13, and the manifold 1 is directly connected to the turbo molecular pump 13 having only the gate valve 12 interposed between the manifold 1 and the turbo molecular pump 13. For this reason, the interior of the processing chamber can be set to a high vacuum of 10⁻⁵ to 10⁻⁶ Torr by the turbo molecular pump 13. In addition, since the turbo molecular pump 13 can control the pressure of the processing chamber with the rotation speed of the rotor, the pressure controllability is high.

Since the conventional vertical heat treatment apparatus has a structure in which the wafer boat is inserted into the processing container from the bottom thereof, exhaust cannot be performed from the bottom. For this reason, in the conventional apparatus, exhaust is performed by an ordinary vacuum pump from a portion other than the bottom portion such as, for example, the side surface of the processing container. In this case, even if a high vacuum turbo molecular pump is used, it must be provided in a portion away from the processing container. This makes it difficult to fully demonstrate the performance of the turbo molecular pump. Therefore, conventionally, the processing of the wafer W has to be performed at a low vacuum of 10⁻³ Torr or more.

For this reason, conventionally, there is a problem in that reaction byproducts (particularly H₂O) cannot be sufficiently exhausted in a short period of time or a problem in that while processing the wafer with O₃ or plasma (radicals or ions), the mean free path thereof is short and the lifetime thereof is short. In addition, there is a problem in that when a complicated and deep pattern exists, it is difficult for the raw material having a low vapor pressure to reach the deepest part of the pattern.

On the other hand, in the present embodiment, the turbo molecular pump 13 is directly installed in the opening portion 11 of the manifold 1 to evacuate the inside of the processing chamber from the bottom. Therefore, the inside of the processing chamber can be set to a high vacuum of 10⁻⁵ to 10⁻⁶ Torr. This makes it possible to solve the aforementioned problems.

For example, it is possible to sufficiently exhaust reaction byproducts in a short time. This makes it possible to enhance the processing performance particularly by ALD. In addition, by increasing the lifetime of O₃ or plasma (radicals or ions), it is possible to enhance the processing ability using the O₃ or plasma. Even by remote plasma, it is possible to allow radicals or ions to reach the wafer without deactivating them. Furthermore, it is possible to use a low vapor pressure raw material which has a hard time reaching the deepest part of the pattern and which has been difficult to apply conventionally. For example, hafnium chloride (HfCl₄) having a low vapor pressure can be used when an HfO₂ film which is a high-k film is formed by ALD.

An annealing process and an oxidizing process are performed at a high temperature. By selecting the turbo molecular pump 13 having high temperature specifications, it is possible to use the turbo molecular pump 13 at a temperature of up to 1000 degrees C. and to sufficiently cope with the annealing process and the oxidizing process. In addition, the high-temperature high-vacuum annealing process which has been carried out by a single wafer processing apparatus can be performed by the vertical batch type apparatus described above. By supplying another gas, it is possible to cope with an additional process performed before and after the high-vacuum annealing process.

In addition, a large volume of exhaust gas is required for the processing performed in the vertical substrate processing apparatus, particularly for the ALD film formation. It is possible to comply with this requirement by using a turbo molecular pump capable of coping with a high back pressure as the turbo molecular pump 13.

Furthermore, when the substrate processing apparatus 100 of the present embodiment is used for etching, particularly when the etching of a deposition-etching-deposition process is performed to embed a fine recess in a void-less manner, the controllability of the etching rate should be enhanced. Since the turbo molecular pump 13 can be controlled at high pressure ranges, it is possible to enhance the controllability of the etching rate.

Moreover, since the high-vacuum processing can be performed by the turbo molecular pump 13 as described above, it is possible to obtain a high quality film when forming an epitaxial film by thermal CVD or plasma CVD.

After performing the appropriate processing in the substrate processing apparatus 100 as described above, a purge gas is introduced into the processing chamber to purge the inside of the processing chamber, and the inside of the processing chamber is returned to atmospheric pressure. Then, the container unit 8 is moved up to the retracted position, and the processed wafers W are unloaded by the transfer device 4.

### <Substrate Processing System>

Among the components of the substrate processing apparatuses 100 described above, the wafer boat 3, the gas introduction member 6, the exhaust mechanism 5 and the container unit 8 may be used as one substrate processing part. A plurality of substrate processing parts may be implemented in a system. A transfer device 4 and a gas supply mechanism 7 common to the substrate processing parts may also be provided. Thus, a cluster type processing system may be configured.

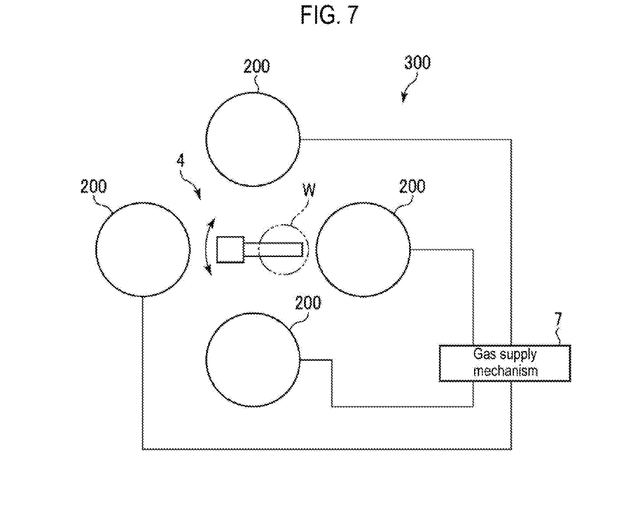

FIG. 7 is a plan view showing a main part of such a substrate processing system 300. In this embodiment, an example is illustrated in which four substrate processing parts 200 each including a wafer boat 3, a gas introduction member 6, an exhaust mechanism 5 and a container unit 8 are used. By constructing such a substrate processing system 300, it is possible to more efficiently perform substrate processing. Alternatively, gas supply mechanisms 7 may be individually provided in the respective substrate processing parts 200.

In such a substrate processing system 300, each of the substrate processing parts 200 is capable of moving the container unit 8 up and down with an elevating mechanism. Among the plurality of substrate processing parts 200, wafer processing may be performed in the substrate processing part 200 in which the container unit 8 is located at the processing position. Transfer of wafers W may be performed by the transfer device 4 in the substrate processing part 200 in which the container unit 8 is located at the retracted position.

### <Other Applications>

Although the embodiments of the present disclosure have been described above, the present disclosure is not limited to the above embodiments. Various modifications may be made without departing from the spirit thereof.

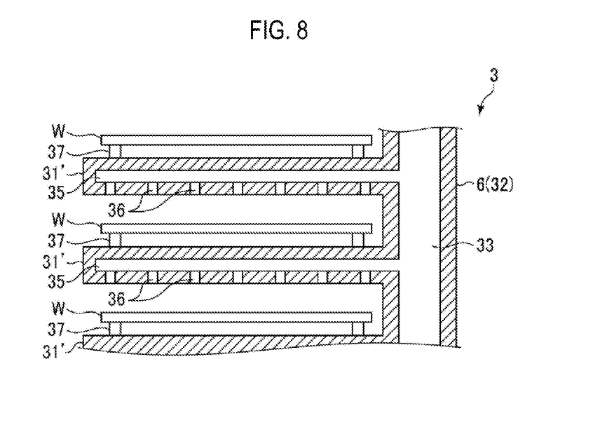

For example, in the above-described embodiments, the shower plate 31 is configured so that the processing gas introduced from the gas introduction member 6 is guided to the center of the shower plate 31 using the branch flow path 34 and is discharged from the gas discharge holes 36 after passing through the gas diffusion space 35. Alternatively, as shown in FIG. 8, a shower plate 31′ for directly introducing the processing gas from the gas introduction member 6 into the gas diffusion space 35 may be used. In this case, although the uniformity of the processing gas is slightly lower than that in the above embodiments, there is an advantage that the shower plate can be made thin.

In the above embodiments, there has been described an example in which the support pillar 32 of the wafer boat 3 is used as the gas introduction member 6. However, the present disclosure is not limited thereto. It is only necessary that the gas introduction member be integral with the wafer boat.

Further, in the above embodiments, the wafer boat 3 is fixed to the manifold which is a base member, and the wafers are not rotated. Alternatively, the wafers may be supported on a turntable or the like so that the wafers can be rotated.

Furthermore, in the above embodiments, the shower plate is provided as a part of the wafer boat. Alternatively, the shower plate may be provided separately from the wafer boat.

Moreover, in the above embodiments, a semiconductor wafer is taken as an example of a substrate to be processed. However, the present disclosure is not limited thereto. It goes without saying that the present disclosure may be applied to other substrates such as a glass substrate, a ceramic substrate and the like.

According to the present disclosure, the processing gas is introduced into the shower plate through the gas introduction member integrated with the substrate holding member and is uniformly discharged from the gas discharge holes of the shower plate directly to the arrangement region of the substrate to be processed. Therefore, the processing gas is uniformly supplied to the substrate from the upper side. The processing which is remarkably higher in uniformity than the conventional processing can be performed on the substrate. When the substrate processing apparatus of the present disclosure is used as a film forming apparatus, the gas flow is supplied from the shower plate above the substrate to the surface of the substrate. It is therefore possible to sufficiently supply the processing gas to a recess such as a trench or the like. This provides an effect that the coverage performance can be enhanced.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus for performing a predetermined process on a substrate to be processed, comprising:
a base member having an opening portion;
a substrate holding member fixedly provided on the base member and configured to hold a plurality of substrates in multiple stages in a vertical direction at predetermined intervals;
a plurality of shower plates provided so as to respectively face the substrates held by the substrate holding member and configured to supply a processing gas to the substrates existing thereunder in a shower shape;
at least one gas introduction member provided integrally with the substrate holding member and configured to introduce the processing gas into the shower plates;
a processing container provided so as to be able to make close contact with the base member and brought into close contact with the base member to define an arrangement space of the substrate holding member as a processing chamber;
a heating device configured to heat the substrates in the processing chamber; and
an exhaust mechanism configured to evacuate the processing chamber through the opening portion of the base member.

2. The apparatus of claim 1, wherein the exhaust mechanism includes a turbo molecular pump connected to the base member via a gate valve and a vacuum pump for rough drawing.

3. The apparatus of claim 1, further comprising:
an elevating mechanism configured to integrally move the processing container and the heating device up and down between a processing position where the processing container and the base member are brought into close contact with each other to define the processing chamber and a retracted position above the substrate holding member; and
a transfer mechanism configured to transfer the substrates to and from the substrate holding member,
wherein predetermined substrate processing is performed when the processing container and the heating device are located in the processing position, and the substrates are transferred to and from the substrate holding member when the processing container and the heating device are located in the retracted position.

4. The apparatus of claim 1, wherein the shower plates are provided as a part of the substrate holding member,
the substrate holding member includes the shower plates provided in multiple stages in the vertical direction, a plurality of support pillars configured to support the shower plates, and a substrate support portion provided on an upper surface of each of the shower plates and configured to support each of substrates, and
each of the shower plates is configured to discharge the processing gas to each of the substrates supported on the upper surface of each of the shower plates existing thereunder.

5. The apparatus of claim 4, wherein at least one of the support pillars is configured as the gas introduction member.

6. The apparatus of claim 1, wherein each of the shower plates includes a gas introduction path configured to introduce the processing gas supplied from the gas introduction member and extending to a central portion of each of the shower plates corresponding to a central portion of each of the substrates existing under each of the shower plates, a gas diffusion space connected to the gas introduction path and having a size substantially corresponding to each of the substrates, and a plurality of gas discharge holes configured to discharge the processing gas in a shower shape from the gas diffusion space to each of the substrates existing under each of the shower plates.

7. The apparatus of claim 1, wherein each of the shower plates includes a gas diffusion space configured to introduce the processing gas supplied from the gas introduction member and configured to diffuse the introduced processing gas, and a plurality of gas discharge holes configured to discharge the processing gas in a shower shape from the gas diffusion space to each of the substrates existing under each of the shower plates.

8. The apparatus of claim 1, wherein a predetermined processing gas is supplied to the gas introduction member from a processing gas supply source of a processing gas supply mechanism.

9. The apparatus of claim 8, wherein a remote plasma source configured to convert the processing gas into plasma is connected to the gas introduction member, and active species generated by the remote plasma source is supplied to the substrates via the gas introduction member and the shower plates.

10. The apparatus of claim 1, further comprising:
a plasma generating mechanism configured to generate plasma in the processing chamber.

11. A substrate processing method using a substrate processing apparatus which includes: a base member having an opening portion; a substrate holding member fixedly provided on the base member and configured to hold a plurality of substrates in multiple stages in a vertical direction at predetermined intervals; a plurality of shower plates provided so as to respectively face the substrates held by the substrate holding member and configured to supply a processing gas to the substrates existing thereunder in a shower shape; at least one gas introduction member provided integrally with the substrate holding member and configured to introduce the processing gas into the shower plates; a processing container provided so as to be able to make close contact with the base member and brought into close contact with the base member to define an arrangement space of the substrate holding member as a processing chamber; a heating device configured to heat the substrates in the processing chamber; and an exhaust mechanism configured to evacuate the processing chamber through the opening portion of the base member, the method comprising:
retracting the processing container and the heating device to a retracted position above the substrate holding member and transferring the substrates to the substrate holding member;
moving the processing container and the heating device downward and bringing the processing container into close contact with the base member to define the processing chamber;
evacuating the processing chamber;
supplying the processing gas introduced from the gas introducing member into the shower plates to the substrates respectively provided under the shower plates in a shower shape to perform predetermined processing;
returning the interior of the processing chamber to an atmospheric pressure after processing; and
retracting the processing container and the heating device to the retracted position above the substrate holding member and unloading the processed substrates from the substrate holding member.

12. The method of claim 11, wherein the exhaust mechanism includes a turbo molecular pump connected to the base member via a gate valve and a vacuum pump for rough drawing, and the processing chamber is made high vacuum by the turbo molecular pump to perform substrate processing.

13. The method of claim 11, wherein a processing gas converted into plasma by a remote plasma source is supplied to the gas introduction member, and active species generated by the remote plasma source is supplied to the substrates via the gas introduction member and the shower plates.

14. The method of claim 11, wherein plasma is generated in the processing chamber to perform plasma processing on the substrates.

15. A substrate processing system, comprising:
a plurality of substrate processing parts each including a base member having an opening portion, a substrate holding member fixedly provided on the base member and configured to hold a plurality of substrates in multiple stages in a vertical direction at predetermined intervals,
a plurality of shower plates provided so as to respectively face the substrates held by the substrate holding member and configured to supply a processing gas to the substrates existing thereunder in a shower shape,
at least one gas introduction member provided integrally with the substrate holding member and configured to introduce the processing gas into the shower plates,
a processing container provided so as to be able to make close contact with the base member and brought into close contact with the base member to define an arrangement space of the substrate holding member as a processing chamber,
a heating device configured to heat the substrates in the processing chamber,
an exhaust mechanism configured to evacuate the processing chamber through the opening portion of the base member, and
an elevating mechanism configured to integrally move the processing container and the heating device up and down between a processing position where the processing container and the base member are brought into close contact with each other to define the processing chamber and a retracted position above the substrate holding member, and
a common transfer device configured to transfer the substrates to and from the substrate holding members of the substrate processing parts.

16. The system of claim 15, wherein substrate processing is performed with respect to the substrate processing part in which the processing container and the heating device are located in the processing position, and the substrates are transferred to and from the substrate holding member by the transfer device with respect to the substrate processing part in which the processing container and the heating device are located in the retracted position.

17. The system of claim 15, wherein the exhaust mechanism of each of the substrate processing parts includes a turbo molecular pump connected to the base member via a gate valve and a vacuum pump for rough drawing.
